(19) United States
(12) Patent Application Publication
(10) Pub. No.: US 2013/0288181 A1
(43) Pub. Date: Oct. 31, 2013

(54) DRAWING APPARATUS, AND METHOD OF MANUFACTURING ARTICLE

(71) Applicant: CANON KABUSHIKI KAISHA, Tokyo (JP)

(72) Inventor: Yusuke Sugiyama, Utsunomiya-shi (JP)

(73) Assignee: CANON KABUSHIKI KAISHA, Tokyo (JP)

(21) Appl. No.: 13/869,483

(22) Filed: Apr. 24, 2013

(30) Foreign Application Priority Data
Apr. 27, 2012 (JP) 2012-103832

(51) Int. Cl. H01J 37/317

(52) U.S. Cl. CPC H01J 37/3174
USPC 430/296; 250/492.22; 250/400

(57) ABSTRACT

The present invention provides a drawing apparatus which performs drawing on a substrate with a charged particle beam, the apparatus comprising a correction device configured to correct drawing data for controlling the drawing, and a drawing device configured to perform the drawing with the charged particle beam based on data corrected by the correction device, wherein the correction device is configured to perform geometrical correction for the drawing data to overlay a drawing region with a target region on the substrate, and then perform proximity effect correction for the drawing data having undergone the geometrical correction.

### BACKGROUND OF THE INVENTION

1. Field of the Invention

The present invention relates to a drawing apparatus, and a method of manufacturing an article.

2. Description of the Related Art

In recent years, with miniaturization and high integration of the circuit pattern of a semiconductor integrated circuit, a drawing apparatus which draws a pattern on a substrate with a charged particle beam (electron beam) is attracting a great deal of attention. The drawing apparatus produces a proximity effect in which an incident charged particle beam scatters in a resist, and the energy of the charged particle beam has influence even at a point spaced apart from the incident point of the charged particle beam. Due to this proximity effect, the line width of the pattern drawn on the substrate, for example, may become different from a designed value. Therefore, in the drawing apparatus, proximity effect correction is of prime importance, so Japanese Patent Laid-Open Nos. 2003-318077 and 2007-005341 propose proximity effect correction methods in which drawing data is corrected and the irradiation conditions of a charged particle beam are changed in accordance with the shape and density of the pattern.

Japanese Patent Laid-Open No. 2003-318077 discloses a method of adding a region, which is adjacent to a divided pattern and is wider than the range of backward scattering, to the divided pattern to generate new graphics data, thereby correcting the proximity effect for the new graphics data. Also, Japanese Patent Laid-Open No. 2007-005341 discloses a method of generating an area density map based on the area density of a divided pattern to correct the proximity effect based on the area density map.

A drawing apparatus generally requires not only proximity effect correction, but also geometrical correction for overlaying a drawing region upon a target region on a substrate in consideration of, for example, the aberration of a charged particle beam, the deflection characteristics of a deflector, or the position and shape of the shot. In the conventional drawing apparatus, proximity effect correction is large-scale processing that takes a long time, and is therefore performed before geometrical correction. However, when proximity effect correction precedes geometrical correction, it is done before the irradiation conditions (the irradiation position and irradiating dose) of a charged particle beam are determined. In addition, the irradiation conditions of a charged particle beam, which are obtained by proximity effect correction, change upon geometrical correction. Hence, the effect of proximity effect correction becomes unsatisfactory in drawing a pattern on the substrate.

### SUMMARY OF THE INVENTION

The present invention provides, for example, a technique advantageous in terms of proximity effect correction.

According to one aspect of the present invention, there is provided a drawing apparatus which performs drawing on a substrate with a drawing apparatus which performs drawing on a substrate with a charged particle beam, the apparatus comprising: a correction device configured to correct drawing data for controlling the drawing; and a drawing device configured to perform the drawing with the charged particle beam based on data corrected by the correction device, wherein the correction device is configured to perform geometrical correction for the drawing data to overlay a drawing region with a target region on the substrate, and then perform proximity effect correction for the drawing data having undergone the geometrical correction.

Further features of the present invention will become apparent from the following description of exemplary embodiments with reference to the attached drawings.

### BRIEF DESCRIPTION OF THE DRAWINGS

FIG. 1 is a view showing the configuration of a drawing apparatus in the first embodiment of the present invention;

FIG. 2A is a block diagram showing correction processing in the conventional drawing apparatus;

FIG. 2B is a block diagram showing correction processing in the drawing apparatus of the first embodiment;

FIGS. 3A and 3B are views showing FSC regions in the drawing apparatus of the first embodiment;

FIG. 4 is a graph showing the energy distribution generated upon forward scattering of a charged particle beam in the resist;

FIG. 5 is a flowchart of the processing details of proximity effect correction in the drawing apparatus of the first embodiment;

FIGS. 6A to 6F are views showing intermediate data generated in the course of proximity effect correction processing in the drawing apparatus of the first embodiment;

FIG. 7A is a view showing the result of a residual correction error when no peripheral region is added;

FIG. 7B is a view showing the result of a residual correction error when a peripheral region is added; and

FIGS. 8A to 8D are views showing the results of correcting an FSC region by performing geometrical correction and proximity effect correction in different orders.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

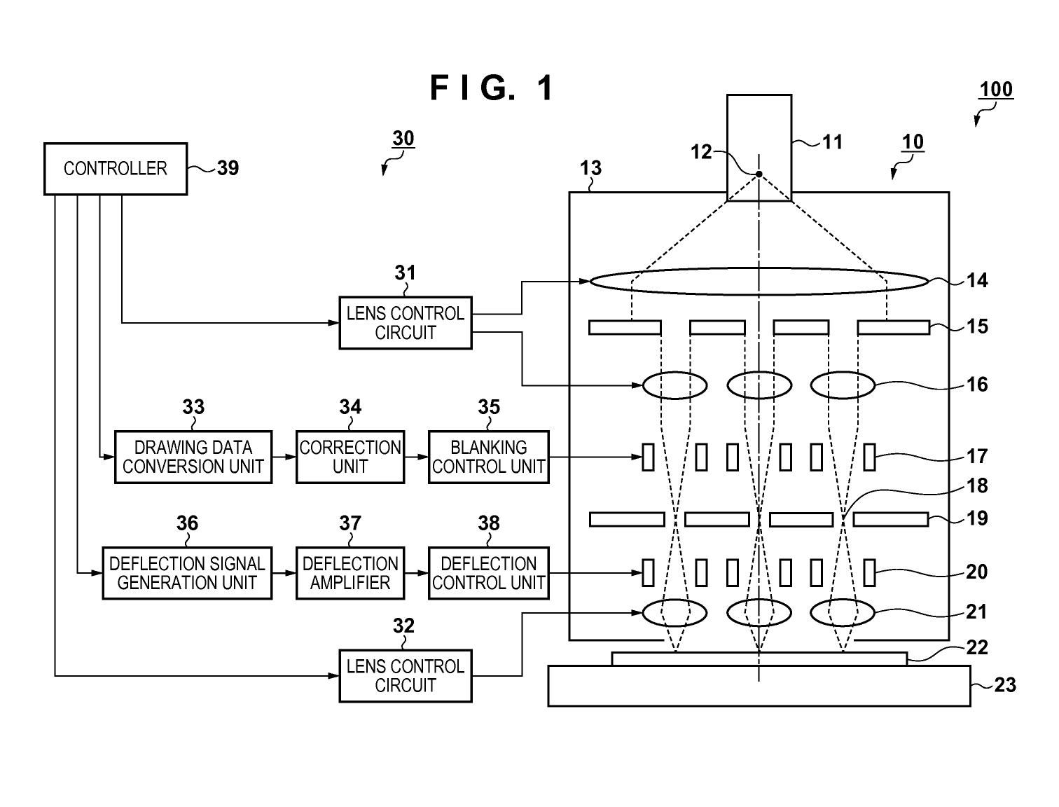

A drawing apparatus 100 that uses a charged particle beam according to the present invention will be described with reference to FIG. 1. The drawing apparatus 100 that uses a charged particle beam includes a drawing system 10 which irradiates a substrate with a charged particle beam to draw a pattern, and a data processing system 30 which controls each constituent part of the drawing system 10.

The drawing system 10 includes a charged particle gun 11, drawing unit 13 (drawing device), and substrate stage 23. The drawing unit 13 includes, for example, a collimator lens 14, aperture array 15, first electrostatic lens 16, blanking deflectors 17, blanking apertures 19, deflectors 20, and second electrostatic lens 21.

A charged particle beam emitted by the charged particle gun 11 forms a crossover image 12, is converted into a collimated beam by the action of the collimator lens 14, and enters the aperture array 15. The aperture array 15 has a plurality of circular apertures arrayed in a matrix, and splits a charged particle beam incident as a collimated beam into a plurality of charged particle beams. The charged particle beams split upon passing through the aperture array 15 enter the first electrostatic lens 16. The first electrostatic lens 16 is formed by, for example, three electrode plates (these three electrode plates are shown as an integrated electrode plate in FIG. 1) having circular apertures. The charged particle beams having passed through the first electrostatic lens 16 form intermediate images 18 of the crossover image 12, and the blanking apertures 19 formed by arranging small apertures in a matrix are set on the plane on which the intermediate images 18 are formed. The blanking deflectors 17 are interposed between the first electrostatic lens 16 and the blanking apertures 19 to individually control blanking of the plurality of charged particle beams. The charged particle beams deflected by the blanking deflectors 17 are blocked by the blanking apertures 19 and do not reach the surface of a substrate 22. That is, the blanking deflectors 17 switch between ON and OFF of the irradiation of the substrate 22 with the charged particle beams. The charged particle beams having passed through the blanking apertures 19 form images of the crossover image 12 on the substrate 22, held on the substrate stage 23, via the deflectors 20 for scanning the charged particle beams on the substrate 22, and the second electrostatic lens 21. Note that the deflectors 20 desirably deflect the charged particle beams in a direction perpendicular to the scanning direction of the substrate stage 23. However, the direction in which the charged particle beams are deflected is not limited to a direction perpendicular to the scanning direction of the substrate stage 23, and the charged particle beams may be deflected at other angles.

The data processing system 30 includes, for example, lens control circuits 31 and 32, drawing data conversion unit 33, correction unit 34 (correction device), blanking control unit 35, deflection signal generation unit 36, deflection amplifier 37, deflection control unit 38, and controller 39. The lens control circuits 31 and 32 control the respective lenses 13, 17, and 21. The drawing data conversion unit 33 converts design data supplied from the controller 39 into drawing data for controlling drawing on the substrate 22. The correction unit 34 divides, corrects, and supplies the drawing data to the blanking control unit 35, which controls the blanking deflectors 17 based on the divided, corrected drawing data. The deflection signal generation unit 36 generates a deflection signal from the design data supplied from the controller 39, and supplies the deflection signal to the deflection control unit 38 via the deflection amplifier 37. The deflection control unit 38 controls the deflectors 20 based on the deflection signal. Also, the controller 39 supplies design data to the drawing data conversion unit 33 and deflection signal generation unit 36, and systematically controls all drawing operations.

In the drawing apparatus 100 of the first embodiment, the aperture array 15 splits the charged particle beam into a plurality of charged particle beams, which are used to draw a pattern in the shot region, as described above. Each blanking deflector 17 deflects a corresponding charged particle beam to draw a pattern in part of the shot region. Hence, data corresponding to each region drawn with a corresponding charged particle beam is extracted from drawing data representing the entire shot region to control each blanking deflector 17 provided to a corresponding charged particle beam. Also, in the drawing apparatus 100 of the first embodiment, due to the proximity effect, the line width of the pattern, for example, becomes different from a designed value, or the aberration of a charged particle beam, the deflection characteristics of a deflector, or the position and shape of the shot vary. To solve this problem, proximity effect correction (PEC) and geometrical correction are performed. Hence, the drawing apparatus 100 in the first embodiment includes the correction unit 34 which extracts drawing data corresponding to each region drawn with a corresponding charged particle beam to correct the extracted drawing data.

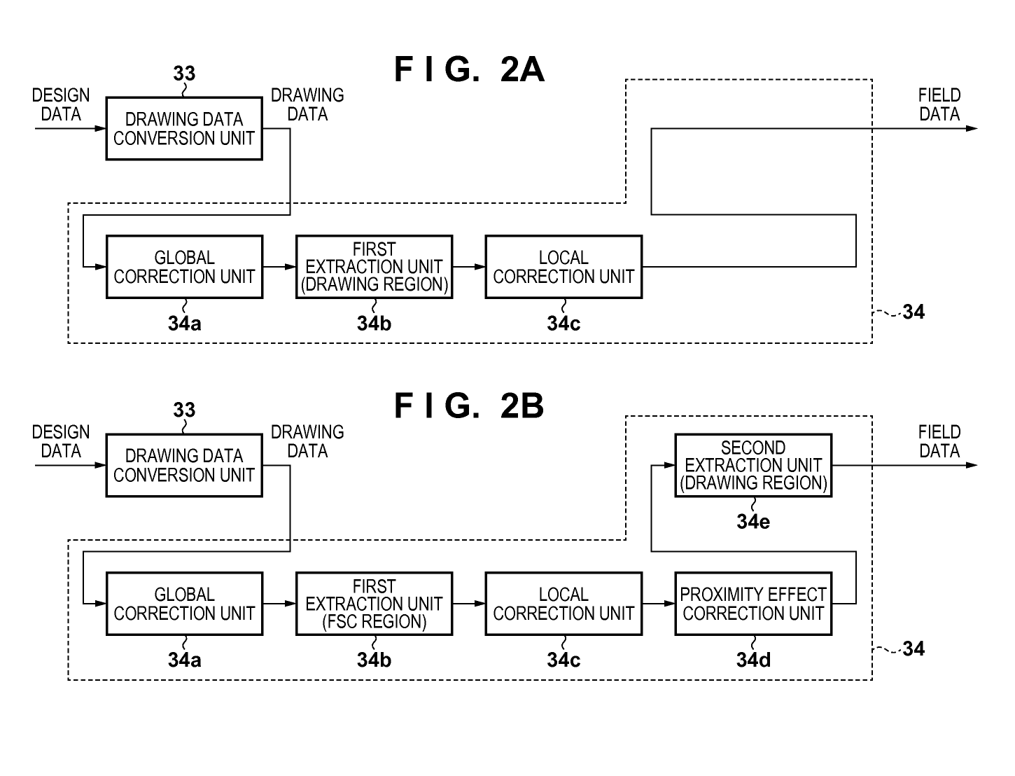

Processing of conversion into drawing data by the drawing data conversion unit 33, and extraction and correction of the drawing data by the correction unit 34 will be described herein with a comparison between the conventional drawing apparatus and the drawing apparatus 100 in the first embodiment. First, conversion into drawing data, extraction from the drawing data, and geometrical correction of the drawing data in the conventional drawing apparatus will be described with reference to FIG. 2A.

The drawing data conversion unit 33 performs conversion into drawing data. The drawing data conversion unit 33 supplies design data from the controller 39, and converts the design data into drawing data for controlling drawing by the drawing system 10. More specifically, the design data is implemented by, for example, CAD data, which is commonly described in the vector format. The drawing data conversion unit 33 converts design data in the vector format into that in the raster format. Note that the vector format means a format representing a pattern to be drawn using, for example, the coordinates of points, or the parameters of equations expressing lines or planes that connect points to each other. The raster format means a format representing a shot region, in which the drawing unit performs drawing on the substrate, using a series of points indicating whether the shot region is to be irradiated with a charged particle beam.

A first extraction unit 34b included in the correction unit 34 extracts a region from the drawing data. The first extraction unit 34b extracts drawing data corresponding to each region to extract, from the shot region, each region continuously drawn with a corresponding charged particle beam. In the conventional drawing apparatus, each region is a drawing region 40 continuously drawn with one charged particle beam. The drawing data extracted in correspondence with the drawing region 40 will be referred to as field data hereinafter. Based on this field data, the blanking control unit 35 controls each blanking deflector 17.

A global correction unit 34a and local correction unit 34c included in the correction unit 34 perform geometrical correction of drawing data. Geometrical correction means correcting drawing data to overlay a drawing region upon a target region on a substrate. The global correction unit 34a is disposed in the preceding stage of the first extraction unit 34b, and performs global correction in which drawing data of the shot region is collectively corrected. Global correction means correcting, for example, variations in deflection position due to the aberration of a charged particle beam to correct, for example, the position, rotation, and shape of the shot. Global correction processing can often be implemented by linear transformation and therefore has a relatively small scale, but it requires an enormous amount of data to be processed, so the shot region may be divided into several shot regions, and this processing may be performed for each divided shot region. The local correction unit 34c is disposed in the succeeding stage of the first extraction unit 34b, and performs local correction in which the respective regions extracted by the first extraction unit 34b are individually corrected. Local correction means correcting, for example, variations in deflection gain of each blanking deflector 17 which deflects a corresponding charged particle beam, and those in irradiation intensity of this charged particle beam. In local correction processing, not only correction which uses a mathematical function, but also correction which uses, for example, an LUT (Lookup Table) is often performed.

With this arrangement, the drawing apparatus performs conversion from design data into drawing data, extraction from the drawing data, and geometrical correction of the drawing data. In the conventional drawing apparatus, proximity effect correction is performed after the drawing data conversion unit 33 converts design data into drawing data, and before the correction unit 34 performs geometrical correction (global correction). However, when proximity effect correction precedes geometrical correction, it is done before the irradiation conditions (the irradiation position and irradiating dose) of a charged particle beam are determined. In addition, the irradiation conditions of a charged particle beam, which are obtained by proximity effect correction, change upon geometrical correction. Hence, when proximity effect correction is performed before geometrical correction, the effect of proximity effect correction becomes unsatisfactory in drawing a pattern on the substrate. To solve this problem, the drawing apparatus 100 in the first embodiment performs proximity effect correction after drawing data extraction and geometrical correction (local correction). Next, the details of processing by the correction unit 34 in the drawing apparatus 100 of the first embodiment will be described with reference to FIG. 2B.

The correction unit 34 in the drawing apparatus 100 of the first embodiment is different from that in the conventional drawing apparatus in the range of data extracted from drawing data by the first extraction unit 34b. Also, a proximity effect correction unit 34d and a second extraction unit 34e are disposed in the succeeding stages of the local correction unit 34c. The first extraction unit 34b, proximity effect correction unit 34d, and second extraction unit 34e in the drawing apparatus 100 of the first embodiment will be described below. Note that the details of processing by the drawing data conversion unit 33, global correction unit 34a, and local correction unit 34c in the drawing apparatus 100 of the first embodiment are the same as in the conventional drawing apparatus, and a description thereof will not be given. Also, FSC (Forward Scattering Correction) will be taken as an example of proximity effect correction in the drawing apparatus 100 of the first embodiment.

The first extraction unit 34b extracts drawing data corresponding to each region drawn with a corresponding charged particle beam to extract this region from the shot region. However, in the drawing apparatus 100 of the first embodiment, proximity effect correction is performed after extraction by the first extraction unit 34b, so when each region is extracted as the drawing region 40, an error, that is, a residual correction error occurs in proximity effect correction at the boundary of this region. To solve this problem, the first extraction unit 34b in the drawing apparatus 100 of the first embodiment extracts each region so as to include not only the drawing region 40 in which drawing is continuously performed with one charged particle beam, but also a peripheral region 41 surrounding it. Each region including both the drawing region 40 and peripheral region 41 will be referred to as each FSC region 42 hereinafter, and drawing data extracted in correspondence with this FSC region 42 will be referred to as FSC data hereinafter. Data (field data) corresponding to the drawing region 40 is extracted from the FSC data by the second extraction unit 34e, as will be described later.

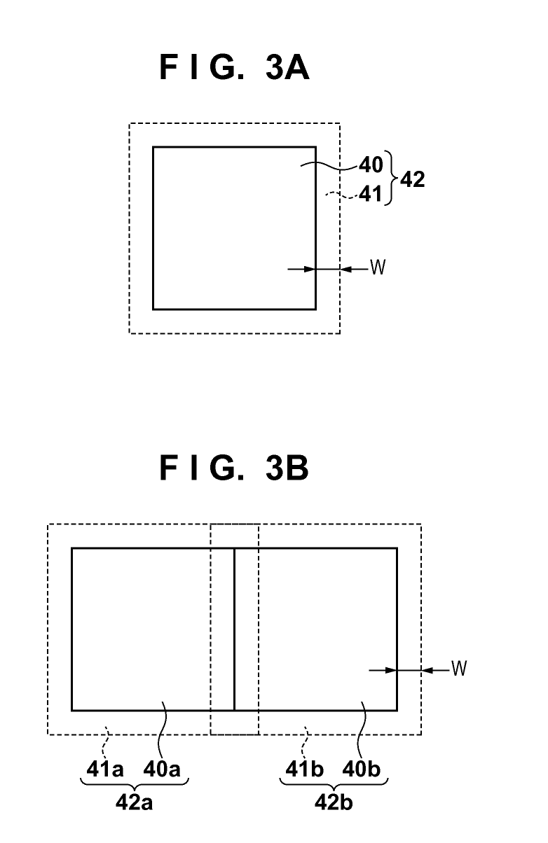

The FSC region 42 is a region obtained by adding the peripheral region 41 with a width W to the periphery of the drawing region 40, and is extracted so as to partially include an adjacent drawing region 40, as shown in FIG. 3A. More specifically, when adjacent drawing regions 40a and 40b are present, and a peripheral region 41a is added to the periphery of the drawing region 40a to extract an FSC region 42a, the peripheral region 41a is extracted to partially overlap the drawing region 40b, as shown in FIG. 3B. When a peripheral region 41b is added to the periphery of the drawing region 40b to extract an FSC region 42b, the FSC region 42b is extracted to partially overlap the drawing region 40a, as in the case wherein the FSC region 42a is extracted. With this operation, the FSC region 42 is extracted so that adjacent regions have an overlapping portion.

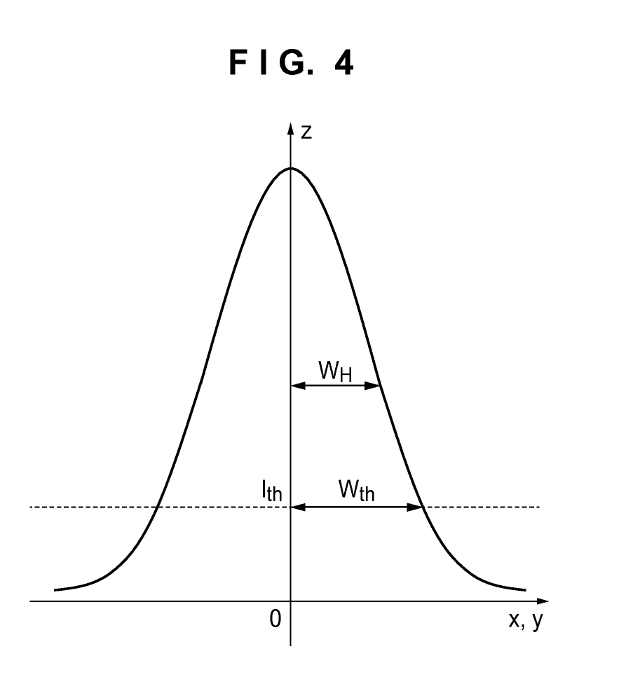

The width W of the peripheral region 41 is set in consideration of the energy distribution generated upon forward scattering of a charged particle beam in the resist. FIG. 4 shows the energy distribution of a charged particle beam generated upon forward scattering in the resist. The energy distribution generated upon forward scattering of a charged particle beam is generally determined in accordance with, for example, the accelerating voltage of the charged particle beam, and is expressed as a Gaussian distribution. The width W of the peripheral region 41 is set to that at which the energy of a charged particle beam incident on the outer peripheral portion of the drawing region 40 halves on the periphery of the drawing region 40, that is, a half width at half maximum W_{H} of the energy distribution generated upon forward scattering of the charged particle beam. With this arrangement, the residual correction error at the boundary of each region can be kept small by setting the width W of the peripheral region 41 to the half width at half maximum W_{H} of the energy distribution. Also, since the half width at half maximum W_{H} of the energy distribution is about several tens of nanometers (about several pixels), the peripheral region 41 is sufficiently smaller than the drawing region 40 (several micrometers on each side), and the amount of increase in proximity effect correction processing as the peripheral region 41 is added falls within a tolerance. Note that the width W of the peripheral region 41 may be set to a half Wₜₕ of a full width, at which the energy becomes equal to or higher than a threshold (>Iₜₕ), in the energy distribution generated upon forward scattering of a charged particle beam (FIG. 4). In this case, the threshold Iₜₕ of the energy is determined based on the irradiating dose or contrast of a charged particle beam in drawing.

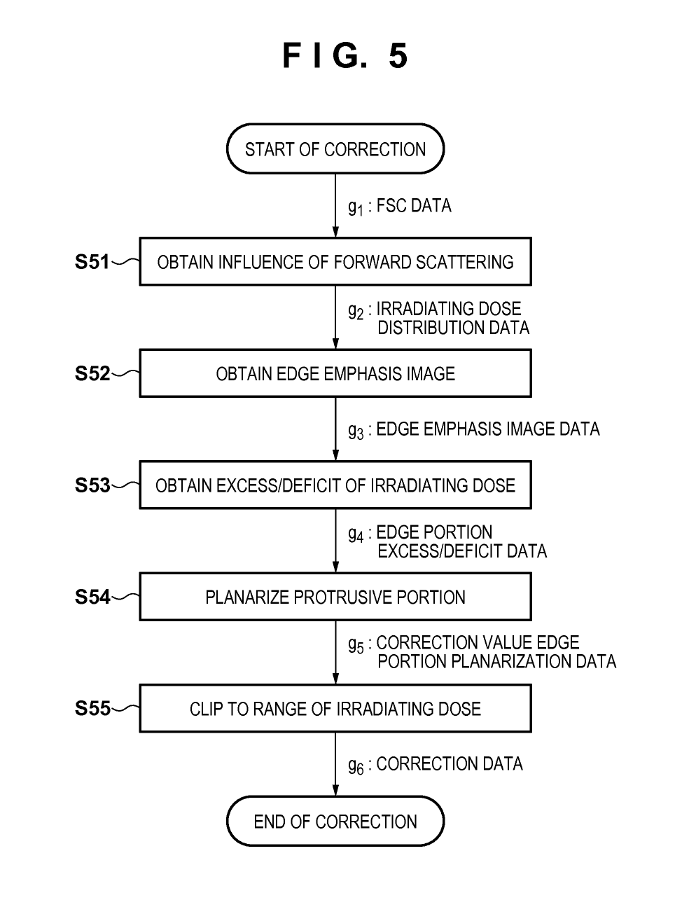

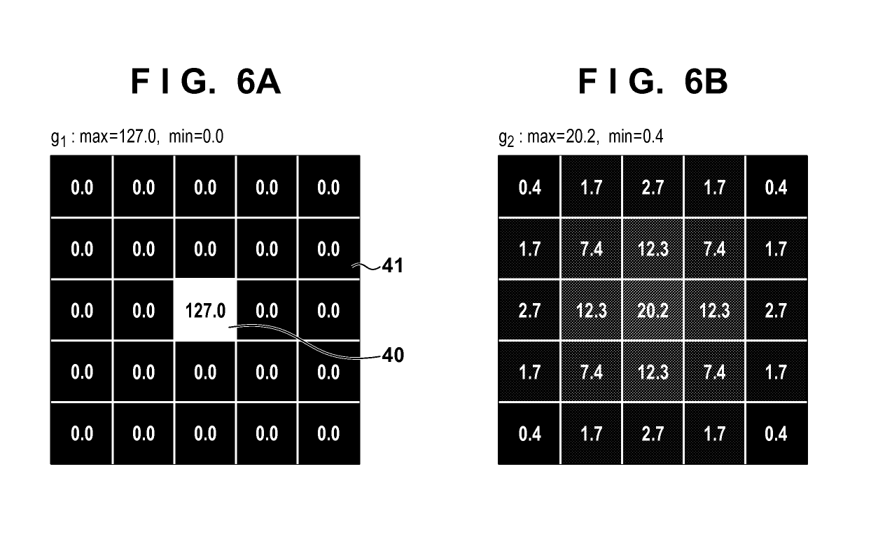

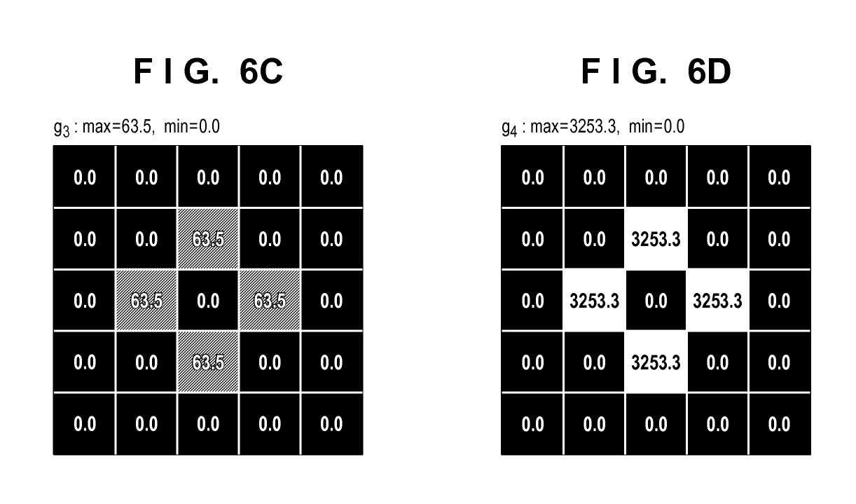

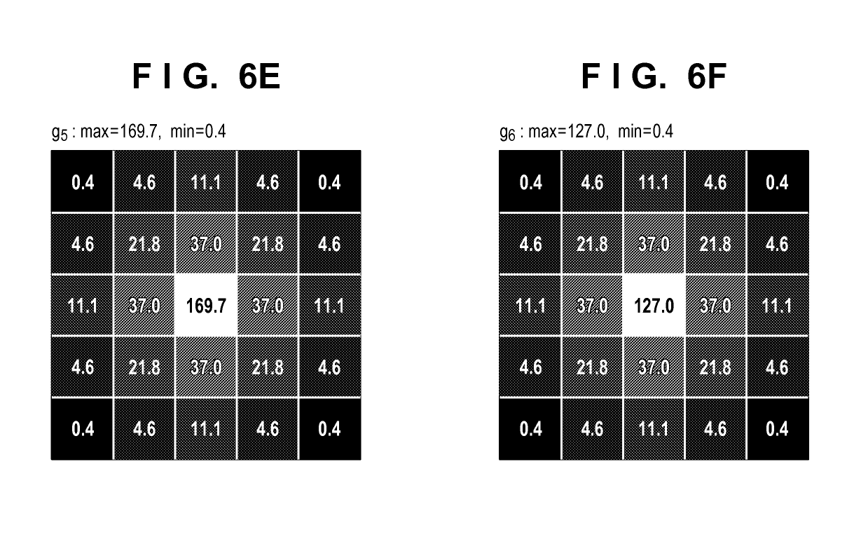

The proximity effect correction unit 34d is disposed in the succeeding stage of the local correction unit 34c, and performs proximity effect correction for FSC data extracted from drawing data. The processing details of proximity effect correction by the proximity effect correction unit 34d will be described herein with reference to FIGS. 5 and 6A to 6F. FIG. 5 is a flowchart of the processing details of proximity effect correction. Also, FIGS. 6A to 6F show the output results of intermediate data in an FSC region 42 (5×5 pixels), in which one pixel at the center is defined as the drawing region 40, and the width W of the peripheral region 41 is 2 pixels, as an example of intermediate data generated in the course of proximity effect correction processing. Note that referring to FIGS. 6A to 6F, the irradiating dose of a charged particle beam is described in each pixel, and variable names g₁ to g₆ of intermediate data, and the maximum and minimum irradiating doses of a charged particle beam in the intermediate data are described in the captions. Also, all the intermediate data g₁ to g₆ shown in FIGS. 6A to 6F, respectively, correspond to the FSC region 42 on the X-Y plane.

In step S51, FSC data g₁ (FIG. 6A) for irradiating only the central drawing region 40 with a charged particle beam is convolved using a first Gaussian filter h₁ by:

g₂=g₁*h₁ (1)

As a result, as intermediate data representing the irradiating dose distribution generated when the drawing region 40 is irradiated with a charged particle beam, irradiating dose distribution data g₂ representing a Gaussian distribution in which the central drawing region 40 is assumed to have a maximum irradiating dose is obtained, as shown in FIG. 6B. Note that the first Gaussian filter h₁ is generated from a Gaussian function p which uses a standard deviation σ₁ in a filter application range H₁ corresponding to the range of forward scattering of a charged particle beam, as given by:

$${h}_{1} = \frac{p}{\sum p} , \\ p = {H}_{1} \cdot exp ( - \frac{{x}^{2} + {y}^{2}}{2 {σ}_{1}^{2}} ) \qquad ( 2 )$$

The first Gaussian filter h₁ may be calculated based on the measurement result of a sample actually irradiated with a charged particle beam.

In step S52, the FSC data g₁ is spatially differentiated and an absolute value is obtained, that is, the FSC data g₁ is partially differentiated with respect to x and y using:

$${g}_{3} = \vert \frac{\partial {g}_{1}}{\partial x} \vert + \vert \frac{\partial {g}_{1}}{\partial y} \vert \qquad ( 3 )$$

and the absolute values of the obtained partial derivatives are added. As a result, as intermediate data in which the irradiating dose of a charged particle beam in the edge portion of the drawing region 40 is emphasized, edge emphasis image data g₃ in which the irradiating doses of pixels (edge portions) adjacent to the central drawing region 40 in the X- and Y-directions are emphasized is obtained, as shown in FIG. 6C.

In step S53, the difference between the irradiating dose distribution data g₂ and the half value of a maximum irradiating dose Iₘₐₓ of a charged particle beam is calculated, and is multiplied by the edge emphasis image data g₃, as given by:

$${g}_{4} = ( \frac{{I}_{max}}{2} - {g}_{2} ) \cdot {g}_{3} \qquad ( 4 )$$

As a result, as intermediate data representing the excess/deficit of the irradiating dose of a charged particle beam in the edge and corner portions of the drawing region 40, edge portion excess/deficit data g₄ representing the excess/deficit of the irradiating dose in a pixel (edge portion) adjacent to the central drawing region 40 is obtained, as shown in FIG. 6D. Note that referring to FIG. 6D, the excess/deficit of the irradiating dose in the corner portion of the drawing region 40 is zero.

The edge portion excess/deficit data g₄ obtained from equation (4) has a delta functional protrusive value in the edge and corner portions of the drawing region 40 (see FIG. 6D). Therefore, in step S54, the edge portion excess/deficit data g₄ is convolved by a second Gaussian filter h₂ to planarize the delta functional protrusive value in the edge portion excess/deficit data g₄, as given by:

g₅=g₁+k(g₄*h₂) (5)

The planarized edge portion excess/deficit data g₄ is multiplied by a parameter k set in advance, and is added with the FSC data g₁ to obtain correction value edge portion planarization data g₅, as shown in FIG. 6E, as intermediate data obtained by applying a correction value to the FSC data g₁. Note that the second Gaussian filter h₂ is generated from a Gaussian function q which uses a standard deviation σ₂ in a filter application range H₂ corresponding to the range of forward scattering of a charged particle beam, as given by:

$${h}_{2} = \frac{q}{\sum q} , \\ q = {H}_{2} \cdot exp ( - \frac{{x}^{2} + {y}^{2}}{2 {σ}_{2}^{2}} ) \qquad ( 6 )$$

Also, the parameter k is associated with the intensity of correction, and is set to an empirical value (zero corresponds to non-correction).

In step S55, the correction value edge portion planarization data g₅ undergoes clip processing, as given by:

g₆=Iₘₐₓ, if g₆>Iₘₐₓ

g₆=Iₘᵢₙ=0, if g₆<Iₘᵢₙ (7)

to fall within the range between the maximum irradiating dose Iₘₐₓ and minimum irradiating dose Iₘᵢₙ (in general, Iₘᵢₙ=0) of a charged particle beam. As a result, correction data g₆ in which the irradiating dose of a charged particle beam falls within a specific range is obtained, as shown in FIG. 6F.

Proximity effect correction processing as described above is performed for all FSC data extracted from drawing data by the first extraction unit 34b. At this time, correction processing for each FSC data may be performed by sequential processing, or parallel processing for a speed-up. The FSC data (correction data) having undergone proximity effect correction is supplied to the second extraction unit 34e.

The second extraction unit 34e extracts field data corresponding to the drawing region 40 from the FSC data (correction data), supplied from the proximity effect correction unit 34d, to extract the drawing region 40 drawn with each charged particle beam from the FSC region 42. The extracted field data is supplied to the blanking control unit 35, which controls the blanking deflectors 17 based on this field data.

As described above, in the drawing apparatus 100 according to this embodiment, FSC data corresponding to the FSC region 42 added with the peripheral region 41 is extracted from drawing data, and proximity effect correction is performed for the FSC data after geometrical correction. The drawing apparatus 100 in the first embodiment with such a configuration can reduce a residual correction error at the boundary of each region, and prevent the effect of proximity effect correction from being inhibited by geometrical correction. Lastly, the effect of performing proximity effect correction for FSC data corresponding to the FSC region 42 added with the peripheral region 41, and the effect of performing proximity effect correction after geometrical correction will be described.

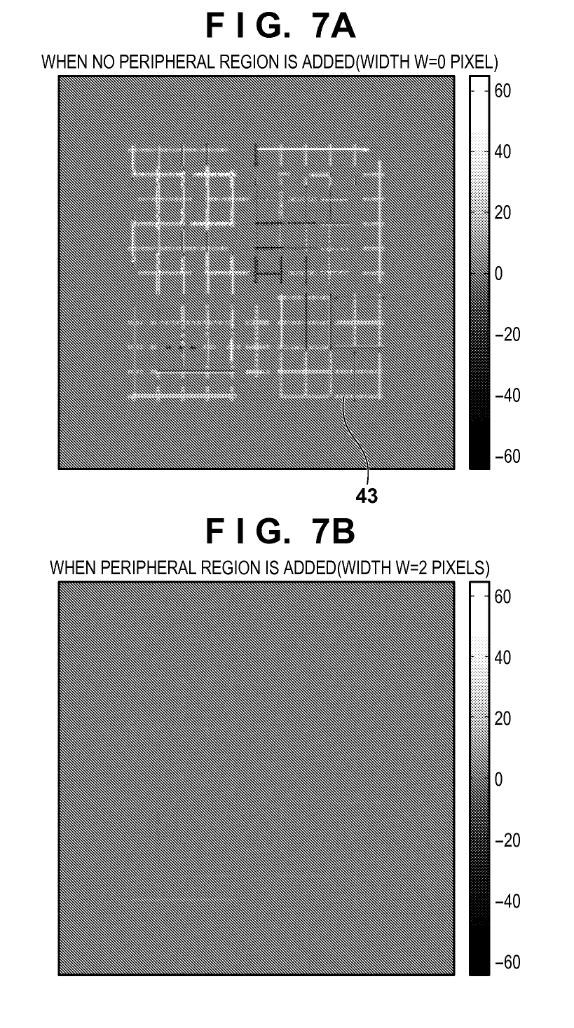

First, the effect of extracting FSC data corresponding to the FSC region 42 obtained by adding the peripheral region 41 to the drawing region 40, and performing proximity effect correction for the FSC data will be described. FIGS. 7A and 7B are views showing the results of residual correction errors in the presence and absence of a peripheral region 41. FIG. 7A shows the case wherein no peripheral region 41 is added to the drawing region 40, and FIG. 7B shows the case wherein a peripheral region 41 is added to the drawing region 40 (the case wherein the width W is 2 pixels). A residual correction error 43 is calculated by subtracting the result of performing proximity effect correction for the entire shot region at once from the result of performing proximity effect correction for each FSC region 42 within the shot region. A white portion in FIG. 7A indicates the residual correction error 43. As can be seen from the calculation result, the residual correction error 43 appears when no peripheral region 41 is added in FIG. 7A, while almost no residual correction error 43 appears, that is, the result of proximity effect correction is significantly better when the peripheral region 41 is added in FIG. 7B. Also, the amount of data is larger by about 14% when a peripheral region 41 is added than when no peripheral region 41 is added. This reveals that only a slight increase in amount of data is sufficient to keep the residual correction error 43 upon proximity effect correction small.

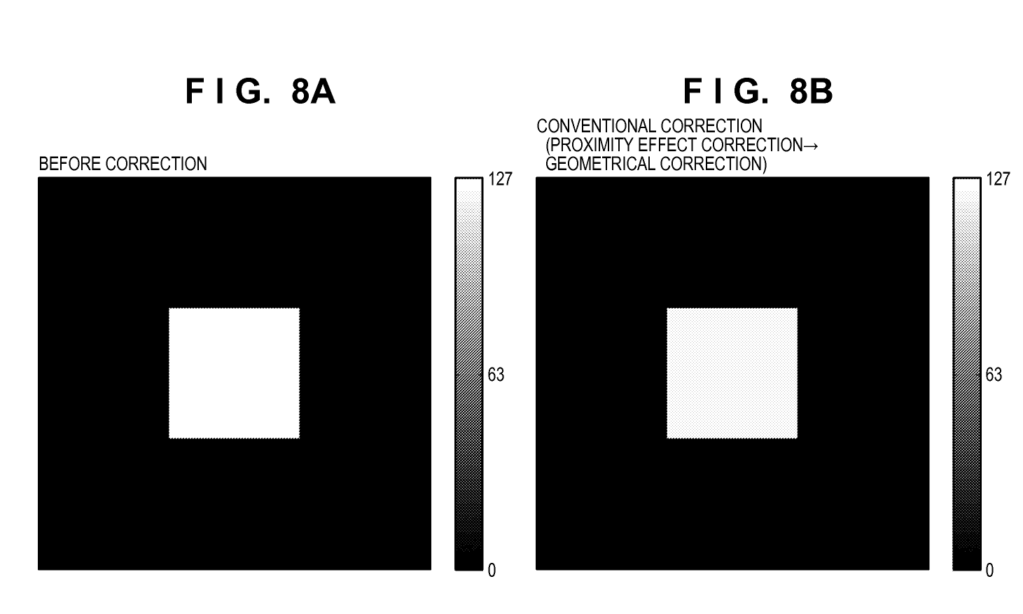

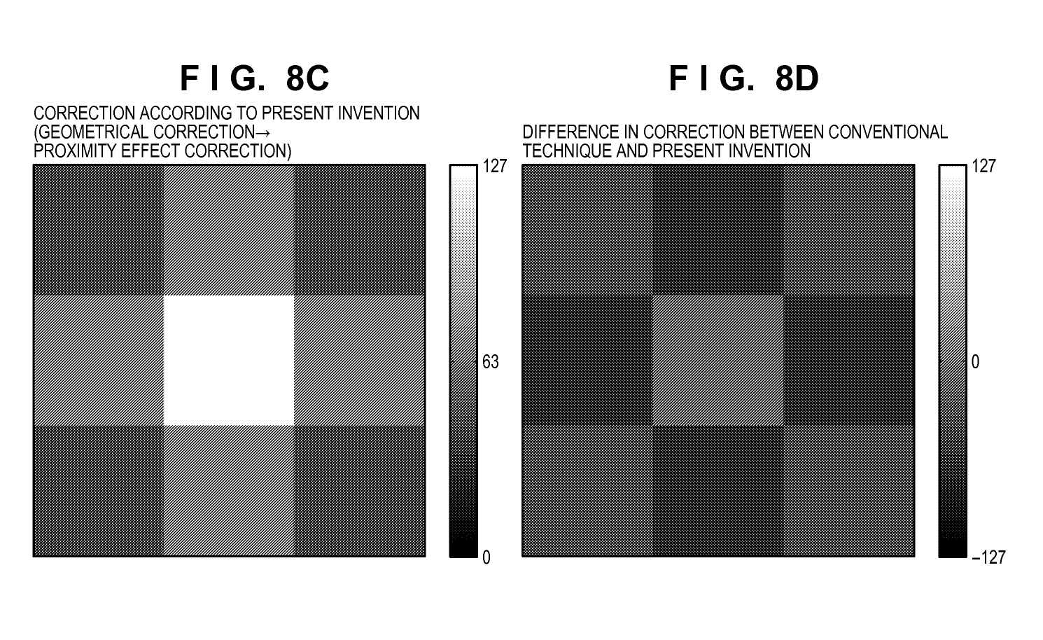

Next, the effect of performing proximity effect correction after geometrical correction will be described. FIGS. 8A to 8D are views showing the results of correcting an FSC region 42 (3×3 pixels), in which one pixel at the center is defined as the drawing region 40, and the width W of the peripheral region 41 is one pixel, by performing geometrical correction and proximity effect correction in different orders. Each pixel is separated by color in correspondence with the irradiating dose of a charged particle beam. FIG. 8A is drawing data before correction, FIG. 8B is drawing data when geometrical correction is performed after proximity effect correction, and FIG. 8C is drawing data (corresponding to the present invention) when proximity effect correction is performed after geometrical correction. Note that in the processing of geometrical correction, a shift is made by 0.1 pixels. The drawing data shown in FIG. 8B remains almost the same as that before correction processing shown in FIG. 8A, while the peripheral region 41 is sufficiently corrected in FIG. 8C. When the difference between the drawing data shown in FIG. 8B and that shown in FIG. 8C is calculated (see FIG. 8D), it becomes as much as a half of the maximum irradiating dose (127). That is, the effect of proximity effect correction is considerably inhibited when geometrical correction is performed, albeit only slightly, after proximity effect correction. Hence, the drawing apparatus 100 in the first embodiment, which performs proximity effect correction after geometrical correction, can exhibit a satisfactory effect of proximity effect correction.

Embodiment of Method of Manufacturing Article>

A method of manufacturing an article according to an embodiment of the present invention is suitable for manufacturing various articles including a microdevice such as a semiconductor device and an element having a microstructure. The method of manufacturing an article according to this embodiment includes a step of forming a latent image pattern on a photosensitive agent, applied onto a substrate, using the above-mentioned drawing apparatus (a step of performing drawing on a substrate), and a step of developing the substrate having the latent image pattern formed on it in the forming step. This manufacturing method also includes subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-103832 filed on Apr. 27, 2012, which is hereby incorporated by reference herein in its entirety.

What is claimed is:

1. A drawing apparatus which performs drawing on a substrate with a charged particle beam, the apparatus comprising:
a correction device configured to correct drawing data for controlling the drawing; and
a drawing device configured to perform the drawing with the charged particle beam based on data corrected by the correction device,
wherein the correction device is configured to perform geometrical correction for the drawing data to overlay a drawing region with a target region on the substrate, and then perform proximity effect correction for the drawing data having undergone the geometrical correction.

2. The apparatus according to claim 1, wherein
the drawing device is configured to perform the drawing with a plurality of charged particle beams,
the correction device is configured to perform proximity effect correction for drawing data for each region of a plurality of regions extracted from a shot region on the substrate, and
the each region includes a drawing region for which drawn is performed with one charged particle beam, and a peripheral region surrounding the drawing region.

3. The apparatus according to claim 2, wherein the drawing device is configured to perform drawing based on the drawing data of the drawing region in the each region having undergone the proximity effect correction by the correction device.

4. The apparatus according to claim 2, wherein a width of the peripheral region is a half width at half maximum of an energy distribution of a charged particle beam having undergone forward scattering in the substrate.

5. The apparatus according to claim 2, wherein a width of the peripheral region is a half of a full width of an energy distribution, an energy of which is not less than a threshold, of a charged particle beam having undergone forward scattering in the substrate.

6. The apparatus according to claim 1, wherein
the drawing device includes a deflector configured to perform blanking of the charged particle beam, and
the drawing data includes data for controlling the deflector.

7. A method of manufacturing an article, the method comprising:
performing drawing on a substrate using a drawing apparatus;
developing the substrate having undergone the drawing; and
processing the developed substrate to manufacture the article,
wherein the drawing apparatus performs the drawing on the substrates with a charged particle beam, the apparatus including:
a correction device configured to correct drawing data for controlling the drawing; and
a drawing device configured to perform the drawing with the charged particle beam based on data corrected by the correction device,
wherein the correction device is configured to perform geometrical correction for the drawing data to overlay a drawing region with a target region on the substrate, and then perform proximity effect correction for the drawing data having undergone the geometrical correction.
